(19) United States
(12) Patent Application Publication
(10) Pub. No.: US 2024/0240303 A1
(43) Pub. Date: Jul. 18, 2024

(54) METAL MASK STRUCTURE, PHOTOMASK FOR PREPARING SHIELDING LAYER, AND METHOD FOR PREPARING METAL MASK STRUCTURE BY USING PHOTOMASK

(71) Applicant: Darwin Precisions Corporation, Hsinchu County (TW)

(72) Inventors: CHIAO-LING HUANG, Hsinchu County (TW); Chi-Wei Lin, Hsinchu County (TW)

(21) Appl. No.: 18/402,784

(22) Filed: Jan. 3, 2024

(30) Foreign Application Priority Data
Jan. 17, 2023 (TW) 112102111

(51) Int. Cl. C23C 14/04; G03F 1/38

(52) U.S. Cl. CPC C23C 14/042; G03F 1/38

(57) ABSTRACT

The invention provides a metal mask structure, a photomask for preparing a shielding layer, and a method for preparing a metal mask structure by using a photomask. The metal mask structure includes a plate, and the plate at least includes: a pattern area formed with at least one slot; a non-pattern area arranged on one side of the pattern area; and a cutting groove extending along an extending direction between the pattern area and the non-pattern area. The cutting groove has an opening formed on a first surface of the plate, and an inner groove surface concave with respect to the first surface. The plate further includes at least one rib structure extending along the extending direction formed on the inner groove surface, and the at least one rib structure does not protrude from the opening.

### CROSS-REFERENCE TO RELATED APPLICATION

This application claims the priority benefit of Taiwan application serial no. 112102111, filed on Jan. 17, 2023. The entirety of the above-mentioned patent application is hereby incorporated by reference herein and made a part of this specification.

### TECHNICAL FIELD

The present invention relates to a metal mask structure, a photomask for preparing a shielding layer, and a method for preparing a metal mask structure by using the photomask. Specifically, the present invention relates to a metal mask structure with a cutting groove, a photomask for preparing a shielding layer, and a method for preparing a metal mask structure with a cutting groove by using the photomask.

### BACKGROUND

In modern technical industry, devices or components with predetermined pattern layouts such as circuit layout or pixel layout are required. In order to prepare such devices or components, a metal mask with a predetermined pattern is required. When using the metal mask to perform the process of forming a predetermined pattern layout, it may need to reserve a certain excess part for stretching or welding to a fixed frame and remove the excess part after fixing the metal mask. Thus, a half-etched cutting groove that is partially etched but not etched through can be prepared on the metal mask in advance. Thereby, the metal mask can be truncated based on the cutting groove to remove the excess part of the metal mask.

There are many obstacles to preparation of the partially-etched cutting groove which is not etched through. Additional etching processes may be required for preparing the cutting groove when preparing the metal mask through processes such as base material preparation, lamination, exposure, development, first etching, second etching, or film removal, etc. Alternatively, the cutting groove can be etched and prepared at the same time when the predetermined pattern is etched. However, the above-mentioned method may unexpectedly increase the complexity of preparing the metal mask, or may cause defects such as under etching or over etching due to differences in depth and width between the cutting groove and the predetermined pattern. Therefore, it would be desirable to develop a technique that forms the partially-etched cutting groove and thereby forms the metal mask with the cutting groove which has predetermined specifications without under-etching or over-etching.

### SUMMARY

In order to solve the above problems, a metal mask structure which includes a plate is provided according to an embodiment of the invention. The plate at least includes: a pattern area formed with at least one slot, a non-pattern area disposed on one side of the pattern area, and a cutting groove extending along an extending direction between the pattern area and the non-pattern area. The cutting groove has an opening formed on a first surface of the plate and an inner groove surface concave with respect to the first surface. The plate further includes at least one rib structure, which extends along the extending direction and is formed on the inner groove surface. The at least one rib structure does not protrude from the opening.

Another embodiment of the invention provides a photomask for exposing and developing a material layer to prepare a shielding layer. The shielding layer is configured to shield the first surface of the plate during the etching process for preparing a metal mask structure as described above. The photomask is configured corresponding to the metal mask structure, and the photomask at lease includes: at least one light shielding portion corresponding to the at least one slot to be formed; at least two light shielding sub-portions extending along a longitudinal direction and adjacently arranged side by side in a transverse direction perpendicular to the longitudinal direction. The at least two light shielding sub-portions jointly correspond to the cutting groove to be formed. One or more spacing sections between the at least two light shielding sub-portions corresponds to the at least one rib structure to be formed.

Yet another embodiment of the invention provides a method for preparing a metal mask structure, including: preparing a plate, disposing a material layer on a first surface of the plate, exposing and developing the material layer based on the photomask described above, and by using a shielding layer resulted from the step of exposing and developing the material layer as a mask, performing a chemical etching process to etch a portion of the plate that is not covered by the shielding layer to form the metal mask structure or a semi-finished product of the metal mask structure.

According to the metal mask structure, the photomask for preparing a shielding layer, and the method for preparing the metal mask structure by using the photomask described in the embodiments of the invention, the etching defects can be reduced or avoided. Specifically, by disposing multiple predetermined etching lines, the cutting groove with the rib structure can be simultaneously formed when the predetermined pattern is formed. As described above, according to such a configuration, the cutting groove can be etched at the same time as the predetermined pattern is etched, simplifying the preparation process of the cutting groove. In addition, the cutting groove can have the predetermined width and etching degree, so the residual thickness of the metal mask structure corresponding to the cutting groove can be prevented from being too small; thereby unexpectedly erosion or truncation can be prevented. Accordingly, the process and the product of preparing the cutting groove can be simplified and improved.

### BRIEF DESCRIPTION OF THE DRAWINGS

FIG. 1 is a schematic top view diagram of a metal mask structure with the cutting groove according to an embodiment of the invention.

FIG. 2 is a cross-sectional schematic diagram along a section line X-X′ of the section R of FIG. 1 according to an embodiment of the invention.

FIG. 3 is an enlarged schematic diagram of the cutting groove of FIG. 2 according to an embodiment of the invention.

FIG. 4 is an enlarged schematic diagram of the cutting groove and the slot according to another embodiment of the invention.

FIG. 5A and FIG. 5B are schematic diagrams of the cutting grooves formed on the corresponding surfaces of opposite ends of the slot according to different embodiments of the invention.

FIG. 6 and FIG. 7 are schematic diagrams showing the relative dimension of sections of the cutting groove according to different embodiments of the invention.

FIG. 8 is a schematic flow chart of preparing the metal mask structure with the cutting groove according to an embodiment of the invention.

FIG. 9 is a schematic flow chart of step S100 of preparing the metal mask structure with the cutting groove according to an embodiment of the invention.

FIG. 10 is a schematic flow chart of step S200 of preparing the metal mask structure with the cutting groove according to an embodiment of the invention.

FIG. 11 is a schematic flow chart of step S300 of preparing the metal mask structure with the cutting groove according to an embodiment of the invention.

FIG. 12A and FIG. 12B are schematic flow charts of step S400 of preparing the metal mask structure with the cutting groove according to an embodiment of the invention.

FIG. 13A and FIG. 13B are schematic diagrams of a finished product or a semi-finished product of the metal mask structure according to an embodiment of the invention.

FIG. 14 is a schematic diagram showing the configuration of the finished metal mask structure corresponding to the photomask used in the process of preparing the metal mask structure according to an embodiment of the invention.

FIG. 15 is a schematic view showing the etching line configuration and the photographs of corresponding finished cutting groove according to an embodiment of the invention.

### DETAILED DESCRIPTION

Various embodiments are to be described below, and a person with ordinary knowledge in the art can easily understand the spirit and principles of the present invention by referring to the accompanying drawings. However, although some specific embodiments are to be specifically described herein, these embodiments are only illustrative and are not to be considered restrictive or exhaustive in all aspects. Therefore, various changes and modifications of the present invention should be obvious and easily achieved for those with ordinary knowledge in the art without departing from the spirit and principles of the present invention.

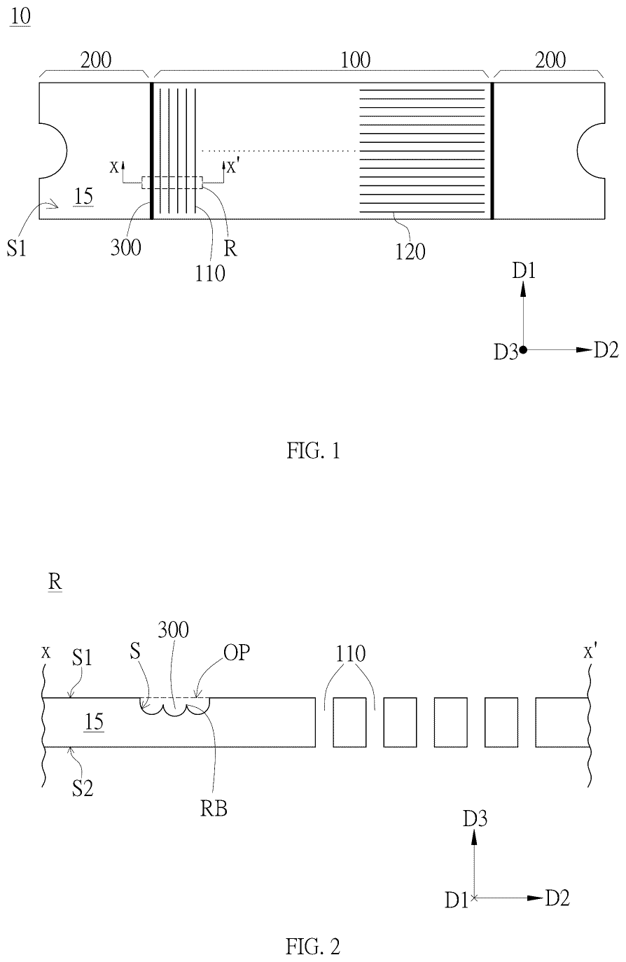

Referring to FIG. 1, a metal mask structure 10 which includes a plate 15 is provided according to an embodiment of the invention. The plate 15 at least includes: a pattern area 100, a non-pattern area 200 disposed on one side of the pattern area 100, and a cutting groove 300 extending along an extending direction D1 between the pattern area 100 and the non-pattern area 200. The pattern area 100 can be a designed section corresponding to a predetermined pattern when the metal mask structure 10 is used to prepare the predetermined pattern of a circuit layout or a pixel layout for other devices or components, and the non-pattern area 200 can be a section outside of the designed section. For example, the non-pattern area 200 can be used for stretching the metal mask structure 10 and can be provided as clamping claws at two sides of the pattern area 100, and the invention is not limited thereto. The non-pattern area 200 can be any part that may be separated from the pattern area 100 in the later process, and the number and location of the non-pattern areas 200 are not limited to those provided in the specification and the accompanied drawings.

According to the embodiment, the pattern area 100 is formed with at least one slot, which is, for example but not limited to, used for material evaporations of devices or components through the full-etched slot (i.e., etching through the plate 15). The pattern area 100 can be configured with slots of various shapes, angles, or directions according to the design of a predetermined pattern. For example, as shown in FIG. 1, one or more slots 110 can be disposed along the extending direction D1 of the cutting groove 300, and/or one or more slots 120 can be disposed along a transverse direction D2, which is perpendicular to the extending direction D1 of the cutting groove 300. However, these configurations of the slots 110 and 120 are only examples, and the invention is not limited thereto.

The following descriptions will be mainly based on the slots 110 and the cutting groove 300, which extend along the same extending direction D1. Accordingly, similar descriptions can be deduced for the slots of other configurations and will not be elaborated.

Please refer to FIG. 2, which shows an enlarged cross-sectional diagram of a section R including the cutting groove 300 and the slots 110 along a section line X-X′. The cutting groove 300 includes an opening OP and an inner groove surface S. The opening OP is formed on a first surface S1 of the plate 15, and the inner groove surface S is concave with respect to the first surface S1. The cutting groove 300 is only opened on the first surface S1 and does not extend to a second surface S2 of the plate 15. The second surface S2 is opposite to the first surface S1. In contrast, the slot 110 penetrates through the plate 15 to form openings on both of the first surface S1 and the second surface S2. In such a configuration, the portion of the plate 15 corresponding to the cutting groove 300 can be kept from being truncated, and the process of forming the predetermined pattern will not be unexpectedly affected. For example, unexpected evaporation of material through the cutting groove 300 can be avoided. If necessary, the plate 15 can be truncated from the cutting groove 300 by concentrating the stress on the cutting groove 300 since the portion of the plate 15 corresponding to the cutting groove 300 is thinner.

According to the embodiment, the plate 15 can further include at least one rib structure RB formed on the inner groove surface S along the extending direction D1. It is to say, the cutting groove 300 can have one or more rib structures RB, which extend along the extending direction D1 of the cutting groove 300. In an embodiment, the at least one rib structure RB preferably does not protrude from the opening OP in a thickness direction D3, which is perpendicular to the extending direction D1 and the transverse direction D2, so the cutting groove 300 can remain internally communicated.

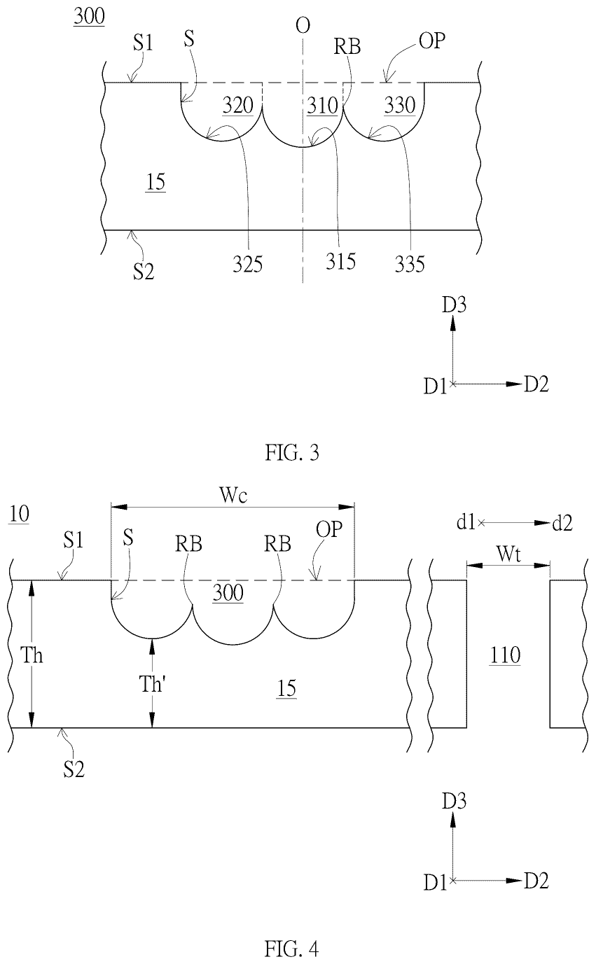

Referring to an enlarged schematic diagram of the cutting groove 300 of FIG. 3, in the embodiment, the height of at least one rib structure RB protruding from the inner groove surface S of the cutting groove 300 does not exceed a reference plane of the first surface S1 in the thickness direction D3, thereby dividing the cutting groove 300 into at least two communicated sections, such as sections 310, 320, 330. For example, the first section 310, the second section 320, and the third section 330 at least partially communicate with each other under the first surface S1. Corresponding to these sections, portions 315, 325, and 335 of the inner groove surface S of the cutting groove 300 separated by the at least one rib structure RB can be formed into concave (curved) surfaces. Thus, the whole inner groove surface S can be considered as a wave-like surface, which is not a single smoothly concave-curved surface, but has a surface with turning portion(s) corresponding to the rib structure(s) RB. According to some embodiments, the rib structure RB can have a wavy shape and serve as a turning node of the portions of the inner groove surface S corresponding to the adjacent sections.

According to different embodiments of the invention, the number of sections of the cutting groove 300 separated by the rib structure(s) RB can be varied. In the specification, the descriptions will be mainly based on two rib structures RB, which divide the cutting groove 300 into three sections. For example, the first section 310 is located at the center O of the cutting groove 300 while the second section 320 and the third section 330 are located at two sides of the first section 310. As described above, people skilled in the art can deduce other variations based on the above example, and the specification will not elaborate hereinafter.

Please refer to FIG. 4, which partially illustrates relative dimensions of the cutting groove 300 and the exemplary slot 110 of the metal mask structure 10 shown in FIGS. 1 to 3. As described above, according to the embodiment, the plate 15 includes the second surface S2 opposite to the first surface S1, and a vertical distance or plate thickness Th′ between the inner groove surface S and the second surface S2 is larger than or equal to 6 μm, i.e., Th′≥6 μm. It is to say, the closest distance between the second surface S2 and the cutting groove 300 can be at least 6 μm. For example, according to some embodiments, the vertical distance (or the plate thickness Th′) between the inner groove surface S and the second surface S2 is 8 μm to 9 μm. As such, the portion of the plate 15 corresponding to the cutting groove 300 can have a predetermined strength, and unexpected truncation can be reduced or avoided.

In addition, according to some embodiments, a vertical distance (or plate thickness Th) between the first surface S1 and the second surface S2 can be between 10 μm to 150 μm. Thus, while the portion of the plate 15 corresponding to the cutting groove 300 can remain a certain strength with the plate thickness Th′, relative to other portions of the plate 15 the portion of the plate 15 corresponding to the cutting groove 300 can still be easily truncated based on expected stress. As such, the robustness of the cutting groove 300 can be further ensured while maintaining the functionality of the cutting groove 300 for cutting.

Next, continue to refer to FIG. 4. According to the embodiment, the opening OP of the cutting groove 300 has an opening width We in a direction perpendicular to the extending direction D1. In detail, the opening OP of the cutting groove 300 has the opening width We along the transverse direction D2. In addition, on the first surface S1 each of the slots 110 has a predetermined width Wt in a direction parallel to a minor axis direction d2 of the slot 110. In an embodiment, the opening width We can be larger than the predetermined width Wt. It is to say, the half-etched cutting groove 300 can have a larger width than the full-etched slot 110, which extends through the plate 15.

Here, the “half-etched” means that the plate 15 is partially etched and not etched through, and does not mean that the plate 15 is exactly etched to the half thickness. However, according to some embodiments, the cutting groove 300 can be formed by exactly etching the plate 15 to the half thickness.

As described above, in this embodiment, the slot 110 extends along the extending direction D1, so the minor axis direction d2 can be actually parallel to the transverse direction D2, and a major axis direction d1 can be actually parallel to the extending direction D1. However, for different slot configurations, the minor axis direction d2 is not necessarily parallel to the transverse direction D2, and the major axis direction d1 is not necessarily parallel to the extending direction D1. Thus, people skilled in the art should understand that the opening width We described herein corresponds to the transverse direction D2 of the cutting groove 300, the predetermined width Wt described herein corresponds to the minor axis direction d2 of the slot, and the opening width We and the predetermined width Wt can be designed as widths measured along the same direction or different directions.

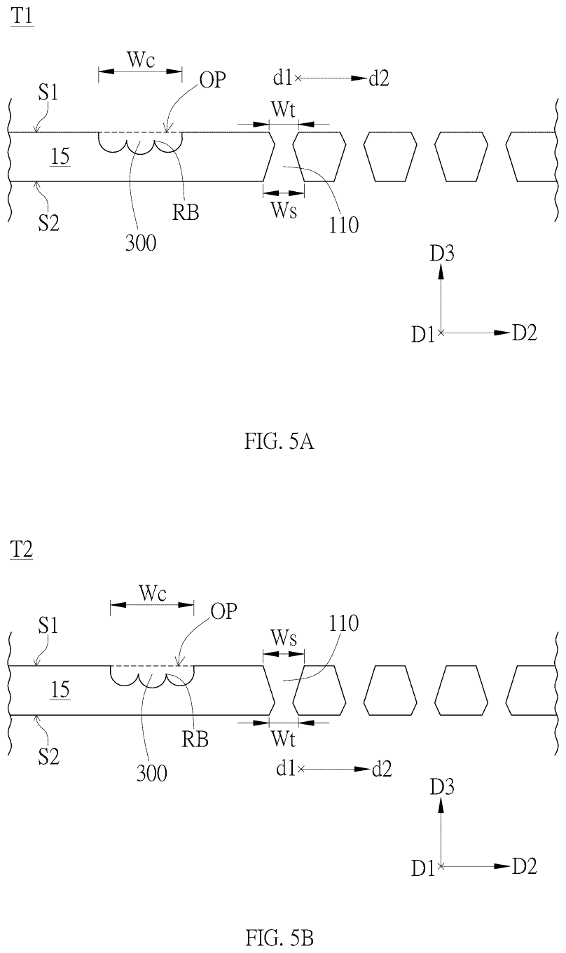

Furthermore, according to some embodiments, referring to configurations T1 and T2 shown in FIGS. 5A and 5B, the slot 110 running through the thickness direction D3 of the plate 15 can have different widths measured along the minor axis direction d2. For example, as shown in FIG. 5A, in the minor axis direction d2 of the slot 110, the slot 110 can have a predetermined width Wt on the first surface S1 and an enlarged predetermined width Ws on the second surface S2, respectively. As described above, the enlarged predetermined width Ws can be larger than the predetermined width Wt. In the configuration T1, the cutting groove 300 can be formed on the first surface S1 on which the predetermined width Wt is formed. However, according to another embodiment, as shown in FIG. 5B, in the minor axis direction d2 of the slot 110, the slot 110 can have an enlarged predetermined width Ws on the first surface S1 and a predetermined width Wt on the second surface S2, respectively. In the configuration T2, the cutting groove 300 can be formed on the first surface S1 on which the enlarged predetermined width Ws is formed.

According to embodiments of the invention, the cutting groove 300 formed on the first surface S1 can be substantially formed on the same surface as the smaller or larger opening of the slot 110. For example, the cutting groove 300 can be formed on the front surface or the back surface of the plate 15 according to processes or configurations. It is to say, the first surface S1 can be the front surface or the back surface of the metal mask structure 10 according to processes or configurations. However, the above is only an example, the invention is not limited thereto, and the slot 110 may not have a wider or narrower variation in width.

In addition, according to some embodiments, no matter whether the cutting groove 300 is formed on the same surface as the smaller opening of the slot 110 (having the predetermined width Wt) or as the larger opening of the slot 110 (having the enlarged predetermined width Ws), the opening width We can be correspondingly larger than the opening of the slot 110. For example, the opening width We can be larger than the predetermined width Wt and the enlarged predetermined width Ws.

According to some embodiments of the invention, the opening width We can be between 80 μm and 120 μm, such as 100 μm, and the predetermined width Wt or the enlarged predetermined width Ws can be between 20 μm and 50 μm, such as 20 μm. However, these are only examples, and the invention is not limited thereto.

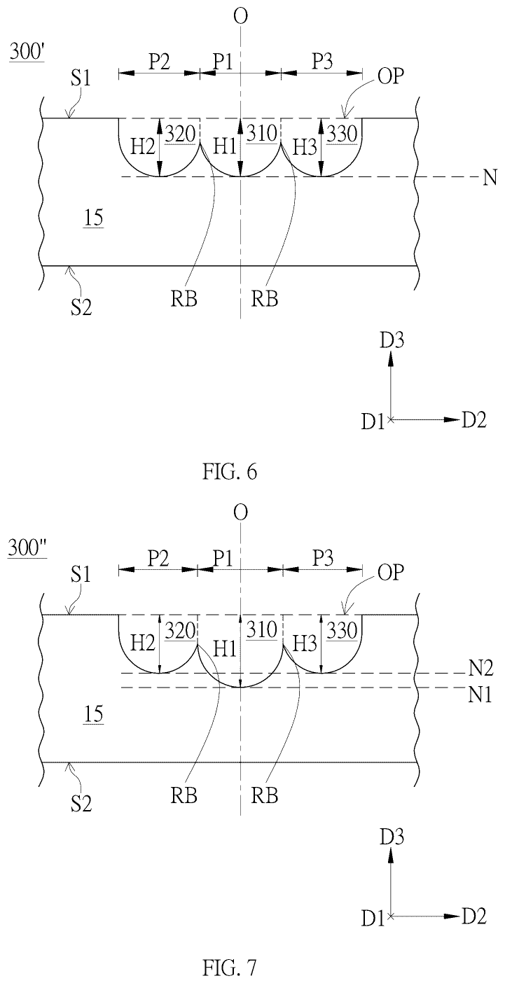

Next, refer to the cutting groove 300′ shown in FIG. 6. In an embodiment of the invention, based on the at least one rib structure RB, the cutting groove 300′ can be divided into at least two sections, such as the first section 310, the second section 320, and the third section 330. As described above, these sections at least include adjacent sections, such as the first section 310 and the second section 320. The cutting groove 300′ has maximum section widths P1 and P2 respectively corresponding to the first section 310 and the second section 320 in a direction perpendicular to the extending direction D1 and parallel to the first surface, and the maximum section widths P1 and P2 are preferably the same. The cutting groove 300′ has maximum section depths H1 and H2 respectively corresponding to the first section 310 and the second section 320 in a direction perpendicular to the first surface S1, and the maximum section depths H1 and H2 are preferably the same. In addition, the relationship between the adjacent first section 310 and second section 320 can be similarly applied to the adjacent first section 310 and third section 330.

As described above, according to the embodiment shown in FIG. 6, the first section 310, the second section 320, and the third section 330 of the cutting groove 300′ can have the same section widths P1, P2, and P3 and the same section depths H1, H2, and H3. The bottoms of the first section 310, the second section 320, and the third section 330 are substantially aligned with a reference plane N. Thus, the uniformity and the robustness of the cutting groove 300′ itself can be improved.

Furthermore, refer to the cutting groove 300″ shown in FIG. 7. According to another embodiment of the invention, based on the at least one rib structure RB, the cutting groove 300″ can be divided into at least two sections, such as the first section 310, the second section 320, and the third section 330. As described above, these sections at least include adjacent sections, such as the first section 310 and the second section 320. The cutting groove 300″ can have a first maximum section width P1 and a second maximum width P2 in a direction perpendicular to the extending direction D1 and parallel to the first surface S1, and the cutting groove 300″ can have a first maximum depth H1 and a second maximum depth H2 in a direction perpendicular to the first surface S1. As shown in FIG. 7, the first section 310 is relatively nearer the center O of the cutting groove 300″ than the second section 320. The first section width P1 is larger than the second section width P2, and the first section depth H1 is larger than the second section depth H2. In addition, the above-mentioned relationship between the adjacent first section 310 and second section 320 can similarly correspond to the adjacent first section 310 and third section 330, and will not be described herein.

As described above, according to the embodiment shown in FIG. 7, the first section 310, the second section 320, and the third section 330 of the cutting groove 300″ can have different section widths P1, P2, and P3 and different section depths H1, H2, and H3. Specifically, the section closer to the center can have a larger section width and a larger section depth. For example, the bottom of the first section 310 can be substantially aligned with the reference plane N1, which is closer to the second surface S2, and the bottoms of the second section 320 and the third section 330 can be substantially aligned with the reference plane N2 that is farther away from the second surface S2. Thereby, when the plate 15 is expected to be truncated based on the cutting groove 300″, the applied stress can be more concentrated on the portion closer to the center O of the cutting groove 300″. Thus, the convenience and accuracy of truncating the plate 15 through the cutting groove 300″ can be expectedly improved.

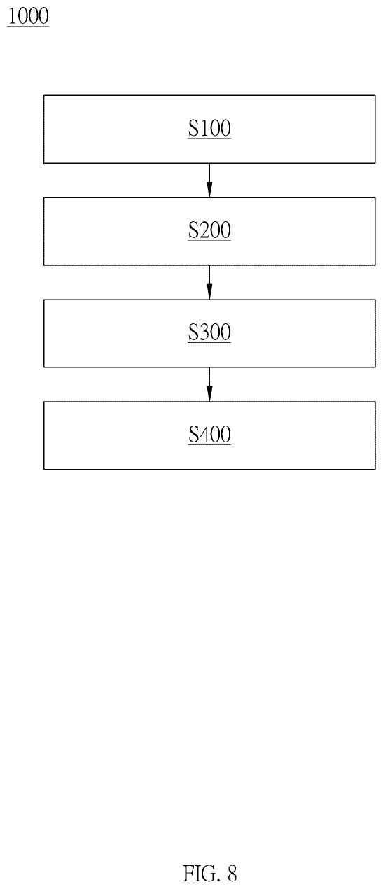

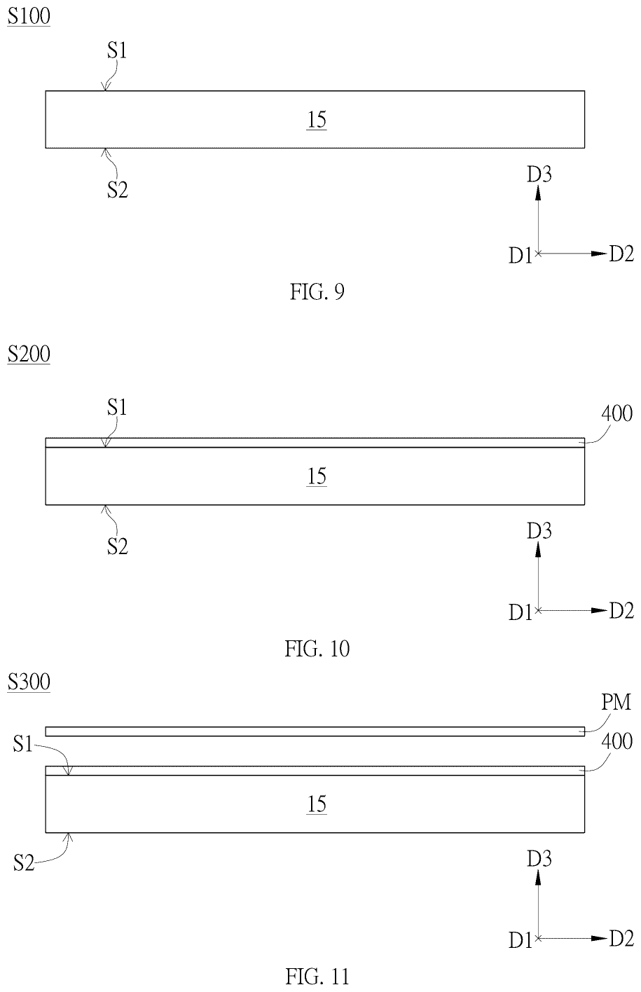

Hereinafter, the method of preparing the above metal mask structure 10 according to an embodiment of the invention will be further described with reference to FIGS. 9 to 14 together with FIG. 8.

As shown in FIG. 8, according to an embodiment of the invention, the method 1000 of preparing the above-mentioned metal mask structure 10 or a similar metal mask structure 10 including the cutting groove 300 with the rib structure RB can include: a step S100 of preparing a plate 15, a step S200 of disposing a material layer, a step S300 of preparing a shielding layer, and a step S400 of performing an etching process. Specifically, as shown in FIG. 9, in the step S100, the plate 15 can be prepared. For example, the plate 15 can be a plate-shaped material made of metal such as Invar alloy, but the invention is not limited thereto. Then, as shown in FIG. 10, in the step S200, a material layer 400 can be disposed on the first surface S1 of the plate 15. For example, the material layer 400 can be a photoresist material. After disposing the material layer 400 such as photoresist material on the plate 15, as shown in FIG. 11, in the step S300, the material layer 400 can be exposed and developed based on a photomask PM. Specifically, the material layer 400 can be exposed and developed based on the pattern design of the photomask PM to construct a specific configuration corresponding to the final required (predetermined) pattern.

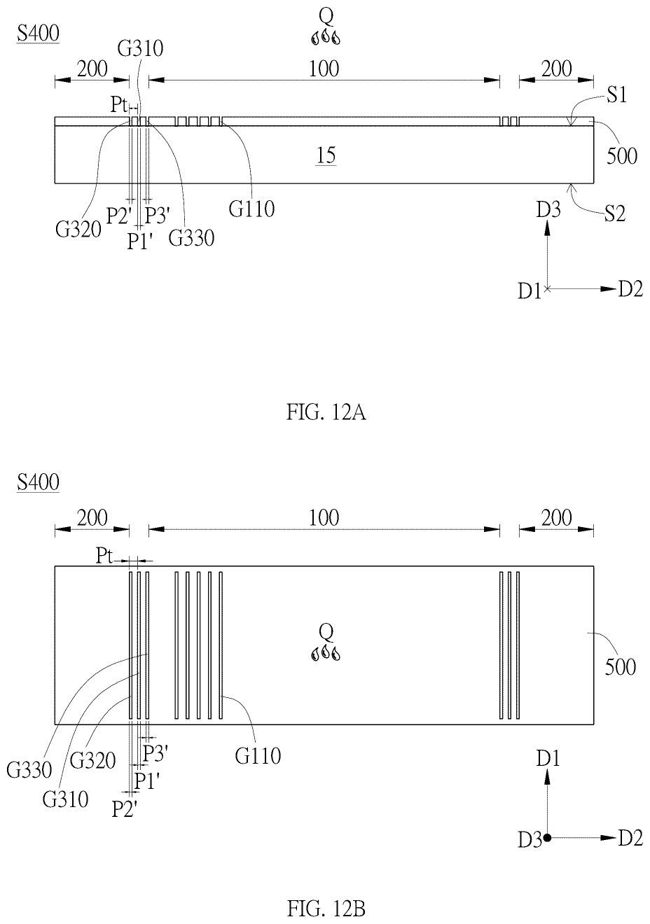

Refer to FIG. 12A and FIG. 12B, which show a schematic cross-sectional view and a schematic top view corresponding to the step S400, wherein a shielding layer 500 formed from the material layer 400 after the step S300 is shown. The shielding layer 500 can include a configuration corresponding to the predetermined pattern and serve as a mask for etching the plate 15 in the step S400. As shown in FIG. 12A and FIG. 12B, the shielding layer 500 can include grooves (or openings) G310, G320, and G330 corresponding to the predetermined cutting groove, and grooves (or openings) G110 corresponding to the predetermined slots. Thereby, the material layer 400, such as the shielding layer 500 formed by the photoresist material after exposure and development, can be used to etch the portion of the plate 15 that is not shielded by the shielding layer 500 by performing the chemical etching process with the chemical etchant Q. It is to say, the chemical etchant Q can enter into the plate 15 and etch the plate 15 through the grooves G310, G320, and G330, so the predetermined etched pattern can be formed on the plate 15.

According to the embodiment, in the step S400, the etching time, the type of the chemical etchant Q, and the widths P1′, P2′ and P3′ of the grooves G310, G320, and G330 along the transverse direction D2 can be designed, so the etched portions corresponding to the grooves G310, G320, and G330 which are arranged side by side are finally partially overlapped and interconnected. It is to say, there is a pitch Pt of adjacent grooves G310 and G320 (or 310 and G330). In the step S400, the chemical etchant Q enters and contacts the plate 15 through the grooves G310, G320, G330. However, as the isotropic etching of the chemical etchant Q continues, the spaces etched through adjacent grooves G310, G320, G330 can at least partially overlap and extend across the pitch Pt. Thus, with the adjacently disposed multiple etching lines as described above (i.e., corresponding to the adjacently disposed grooves G310, G320 and G330) and the designed etching time and etching intensity, the etched ranges can overlap and interconnect, so the defects caused by etching a single cutting line can be reduced or avoided. For example, the etching rate of the cutting groove 300 with a wider width may be too fast compared to the slot 110 of the pattern area 100. Thus, according to the embodiment, the final etching depth of the cutting groove 300 in the thickness direction D3 can be reduced or avoided from being too deep, resulting in insufficient residual thickness (for example, less than 6 μm), and the predetermined opening width We (for example, about 100 μm) of the cutting groove 300 can be satisfied.

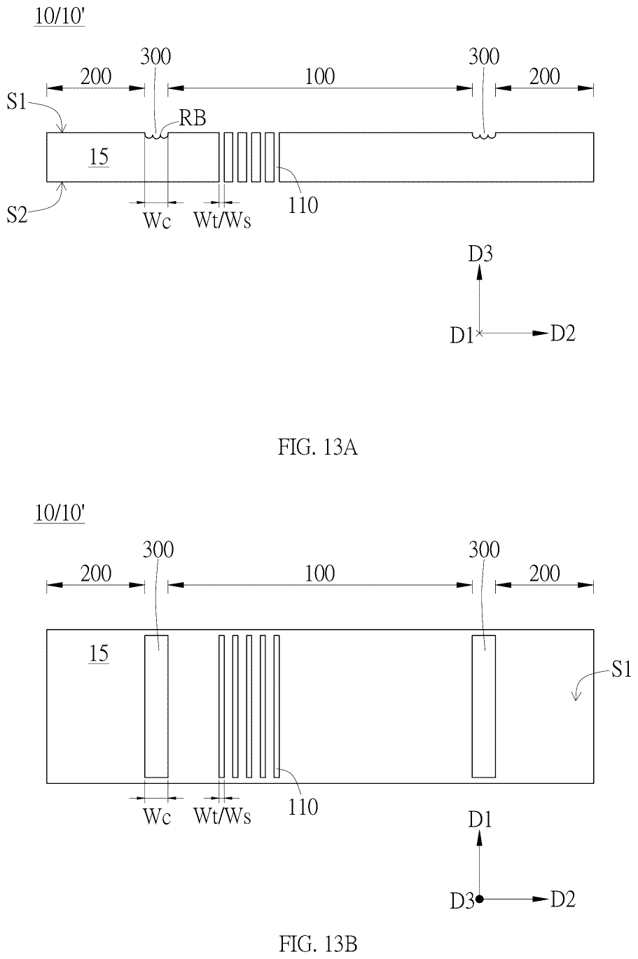

According to the embodiment, refer to FIG. 13A and FIG. 13B, which show the schematic cross-sectional view and the schematic top view after the step S400 is completed, wherein the metal mask structure 10 or the semi-finished product 10′ of the metal mask structure can be formed after the step S400 or other additional steps. As described above, the cutting groove 300 and a portion of the slots 110 can be formed in the step S400. The cutting groove 300 can correspond to the portions etched through the grooves G310, G320 and G330 (i.e., corresponding to the predetermined etching lines) originally arranged side by side in parallel, and the portion of each slot 110 can correspond to the portion etched through each groove G110.

Here, the portion of each slot 110 opened on the first surface S1 can be achieved through the etching step S400. The other portion of each slot 110 opened on the second surface S2 can be achieved by performing an etching process similar to the step S400 on the second surface S2 before or after the step S400, which will not be elaborated herein.

As shown in FIG. 13A and FIG. 13B, after the step S400 is completed, the metal mask structure 10 or the semi-finished product 10′ of the metal mask structure can be formed. The metal mask structure 10 or the semi-finished product 10′ of the metal mask structure can include the cutting groove 300 and the slots 110. The cutting groove 300 is disposed between the non-pattern area 200 and the pattern area 100, and the slots 110 corresponding to the predetermined pattern are formed in the pattern area 100. As described above, in the metal mask structure 10 or the semi-finished product 10′ of the metal mask structure, the opening width We of the cutting groove 300 can be larger than the predetermined width Wt or the enlarged predetermined width Ws of the slot 110.

According to some embodiments, if the cutting groove 300 is etched together with the smaller opening of the slot 110 (which has the predetermined width Wt), the initially predetermined width of the parallel etching lines (i.e., the width of the corresponding groove) can be larger. For example, the widths of the grooves G310, G320, and G330 corresponding to the etching lines of the cutting groove 300 can be configured by using the same width as the groove G110 used for etching the slot 110. In addition, if the cutting groove 300 is etched together with the larger opening of the slot 110 (which has the enlarged predetermined width Ws), the initially predetermined widths of the parallel etching lines (i.e., the width of the corresponding groove) can be smaller. For example, a width being much smaller than the width of the groove G110 for etching the slot 110 can be used to configure the widths of the grooves G310, G320, and G330 corresponding to the etching lines of the cutting groove 300. As described above, in order to decrease or avoid the unexpected over-etching or under-etching when etching the pattern of the slots 110, the widths (e.g. widths P1′, P2′, and P3′) of the etching lines initially arranged side by side can be accordingly adjusted. Thus, when the pattern etching of the slots 110 is completed, the cutting groove 300 resulted from the expected overlapped and interconnected etching lines can be obtained.

As shown in FIG. 13A and FIG. 13B, the number (e.g. 2) of the finally formed rib structures RB can be determined according to the number (e.g. 3) of the initially provided etching lines (i.e., the grooves) of the cutting groove 300. However, the quantity is only used for example, and people skilled in the art should correspondingly understand configurations of other quantity.

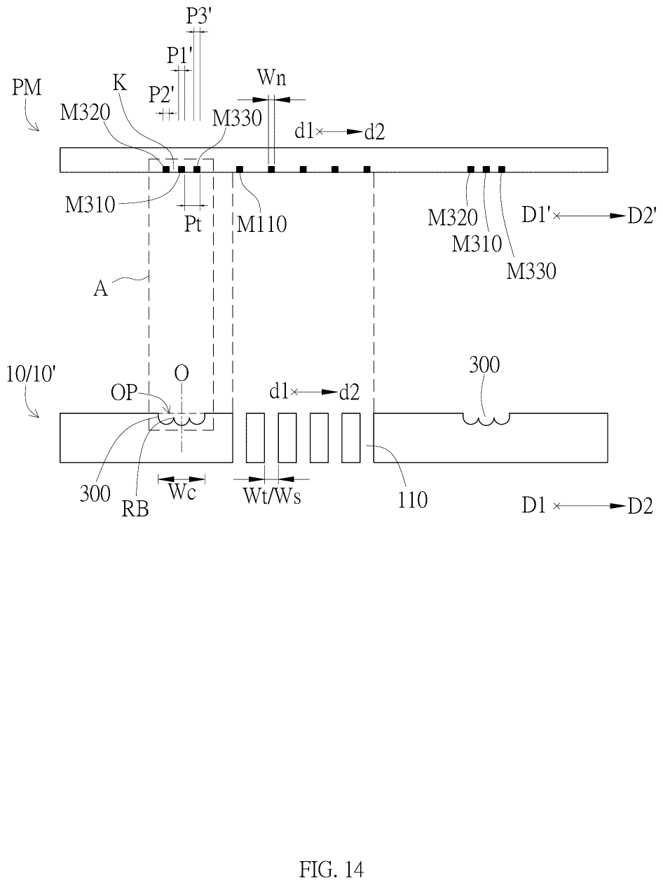

According to some embodiments, in order to perform the process described above, a specially designed photomask PM can be used to expose and develop the material layer 400 to prepare the shielding layer 500 in the step S300 described above. The shielding layer 500 is disposed on the first surface S1 of the plate 15 and prepared for the etching process of the step S400 to produce the metal mask structure 10 or the semi-finished product 10′ thereof. In detail, refer to FIG. 14, which shows the corresponding photomask PM and the finally formed metal mask structure 10 or the semi-finished product 10′ thereof. In an embodiment, according to the arrangement of the metal mask structure 10 or the semi-finished product 10′ thereof, the photomask PM at least includes: at least one light shielding portion M110 and at least two light shielding sub-portions, such as light shielding sub-portions M310, M320, and M330. Referring to the corresponding configuration shown in FIG. 14, the at least one light shielding portion M110 can respectively correspond to one of the predetermined slots 110, and the light shielding sub-portions M310, M320, and M330 can extend along the longitudinal direction D1′ of the photomask PM and be spaced apart and arranged side by side in a transverse direction D2′, which is perpendicular to the longitudinal direction D1′. The light shielding sub-portions M310, M320, and M330 jointly correspond to the predetermined cutting groove 300.

As described above, according to the embodiment, the exposure and development can be performed based on the negative photoresist. Specifically, the material layer 400 such as negative photoresist material layer 400 can be firstly masked by the photomask PM. Thereby, the portions of the material layer 400 shielded by the light shielding portion M110 and the light shielding sub-portions M310, M320, and M330 will not be irradiated by the light during the exposure process and thus cannot be cured. During the subsequent development process, such uncured portions will be removed to form corresponding grooves in the shielding layer 500 for the etching process. As described above, in such a configuration, the arrangement of the light shielding portions and sub-portions of the photomask PM correspond to the slots 110 and the cutting groove 300 of the final metal mask structure 10 or its semi-finished product 10′ after the etching process is completed. However, the invention is not limited thereto. The invention can also be prepared by the positive photoresist, and people skilled in the art can deduce the implementation manner accordingly from the above description. Thus, it will not be elaborated herein.

As described above, in the embodiment, the light shielding portions of the photomask PM correspond to the grooves formed on the shielding layer 500, and the final metal mask structure 10 or the semi-finished product 10′ thereof is chemically etched by using the shielding layer 500. Therefore, based on the predetermined etching process of step S400 which is a chemical wet etching process, the width of the light shielding portion can be smaller than that of the finally formed cutting groove 300 or slot 110.

Specifically, the light shielding sub-portions M310, M320 and M330 respectively include light shielding sub-portion widths P1′, P2′, and P3′ in a direction parallel to the transverse direction D2′ of the photomask PM, and each of the light shielding sub-portion widths P1′, P2′, and P3′ and the sum of the light shielding sub-portion widths P1′, P2′, and P3′ can be smaller than the opening width We of the opening OP of the cutting groove 300 to be formed, wherein the opening width We is measured in the transverse direction D2 perpendicular to the extending direction D1 of the plate 15. In addition, the light shielding portions M110 each includes a light shielding portion width Wn measured in a direction correspondingly parallel to the minor direction d2 of the slot 110, and the light shielding portion width Wn is smaller than the predetermined width Wt or the enlarged predetermined width Ws of the slot 110.

Furthermore, according to some embodiments, in order to reduce or avoid excessive etching of the groove 300 when etching the slot 110, the light shielding sub-portion width P1′, P2′ or P3′ can be less than or equal to the light shielding portion width Wn. Thereby, compared to the slot 110, etching of the cutting groove 300 can be performed in parallel with multiple etching lines based on a similar or smaller width range. As described above, excessive etching can be reduced or avoided by using different etching lines such as the light shielding sub-portions M310, M320, and M330 of small width P1′, P2′ or P3′, and the cutting groove 300 having a width greater than that of the slot 110 can be formed by interconnecting different parallelly arranged etching lines.

According to some embodiments, the light shielding sub-portion widths P1′, P2′ and P3′ corresponding to the etching lines can be individually between 10 μm to 50 μm, and the opening width We resulted from overlapping and interconnecting can be between 80 μm to 120 μm. However, the specific numbers are only examples, and the invention is not limited thereto.

As shown in FIG. 9 to FIG. 14, the shielding layer 500 can be used to mask the first surface S1 of the plate 15 in the step S400 of performing the predetermined etching process; thereby at least a portion of each slot 110 is opened on the first surface S1 (each slot 100 opened on the second surface S2 can be formed by another etching process), and the cutting groove 300 can be formed as a single communicated groove in the region A which corresponds to the light shielding sub-portions M310, M320, and M330.

In such a situation, the spacing sections K between the light shielding sub-portions M310, M320, and M330 of the photomask PM can respectively correspond to the rib structures RB to be finally formed. In detail, the portion of the plate 15 which corresponds to the spacing section K between the light shielding sub-portions M310, M320, and M330 is not directly etched by being exposed through the grooves of the shielding layer 500, and is etched indirectly through the grooves of the shielding layer 500 by finally interconnecting with each other. Thus, at an intersection where the plate 15 is gradually laterally etched through the adjacent grooves of the shielding layer 500, there can remain an incompletely etched portion as the rib structure RB. That is, the rib structure RB is a residual unetched portion resulted from the lateral etching through adjacent grooves of the shielding layer 500.

As described above, the shape of the top of the rib structure RB close to the first surface S1 can be determined according to the overlapping and interconnecting condition resulted from the etching process, and can be formed into a flat top or a pointed top. In addition, the rib structure RB can be formed into a wavy shape due to the isotropic characteristic of chemical etching, so a concave curved surface can be formed from the top of one rib structure RB to the top of another adjacent rib structure RB. However, these are only examples, and the invention is not limited thereto. As described above, according to the actual etching overlapping and interconnecting conditions, the rib structure RB can be naturally generated, and its specific form is not limited thereto.

Furthermore, the specific size of each section of the finally formed cutting groove 300 can also be adjusted by the design of the photomask PM.

For example, according to an embodiment, the light shielding sub-portions M310, M320, and M330 at least include adjacent light shielding sub-portions, such as the first light shielding sub-portion M310 and the second light shielding sub-portion M320, and the light shielding sub-portion widths P1′ and P2′ of the first light shielding sub-portion M310 and the second light shielding sub-portion M320 parallel to the transverse direction D2′ are the same. The above configuration can be similarly applied to the adjacent first light shielding sub-portion M310 and the third light shielding sub-portion M330. Therefore, chemical wet etching of isotropic etching can be used to form the cutting groove (such as the above-mentioned cutting groove 300′ shown in FIG. 6) which has evenly distributed sections, so the overall cutting groove can be more stable and reliable, and sections thereof can be evenly communicated.

On the contrary, according to another embodiment, the light shielding sub-portions M310, M320, and M330 at least include adjacent light shielding sub-portions, such as the adjacent first light shielding sub-portion M310 and the second light shielding sub-portion M320. In addition, the first light shielding sub-portion M310 and the second light shielding sub-portion M320 respectively include a first light shielding sub-portion width P1′ and a second light shielding sub-portion width P2′ parallel to the transverse direction D2′. As described above, the first light shielding sub-portion M310 is closer to the center O of the predetermined cutting groove 300 than the second light shielding sub-portion M320, and the first light shielding sub-portion width P1′ is larger than the second light shielding sub-portion width P2′. In addition, the above configuration can be similarly applied to the adjacent first light shielding sub-portion M310 and the third light shielding sub-portion M330. Therefore, due to the isotropic characteristic of chemical wet etching, when the etching line width is larger, a relatively deeper etching depth can be obtained, thereby forming a cutting groove (such as the above-mentioned cutting groove 300″ shown in FIG. 7) which has a deeper depth near the center O. Thus, when the plate 15 is expected to be truncated, such as configuration can improve the concentration of stress exerted on the cutting groove, so it may be more convenient and accurate to truncate the plate 15 based on the cutting groove.

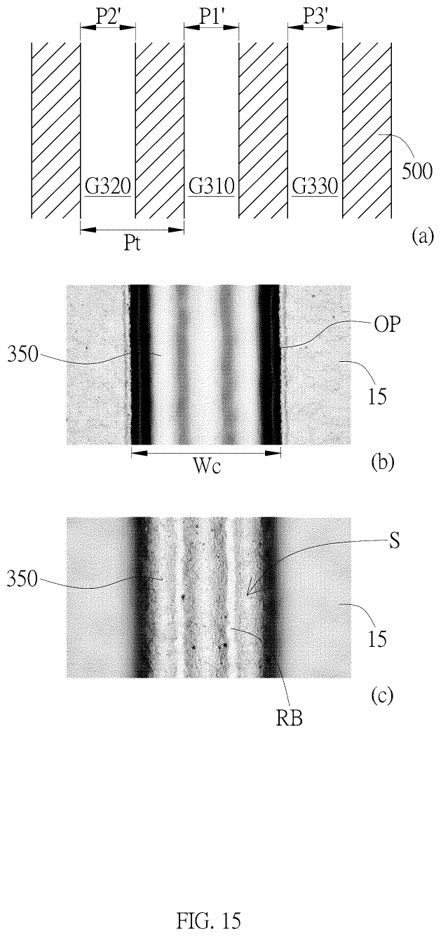

Next, refer to FIG. 15(a), according to an embodiment of the invention, the grooves G310, G320, and G330 can be disposed based on that the above-mentioned widths P1′, P2′, and P3′ are 17 μm, the pitch Pt is 32 μm, and the gaps between different grooves are 15 μm, and the cutting groove 350 can be formed by etching. Referring to FIG. 15(b) (focusing on the opening OP of the cutting groove 350) and FIG. 15(c) (focusing on the bottom surface S and the rib structure RB of the cutting groove 350), the cutting groove 350 can be formed with a large enough opening width We as expected by etching through parallelly adjacent etching lines, and the plate 15 is left with enough thickness; thereby unexpected erosion or truncation of the portion corresponding to the cutting groove 350 can be reduced or avoided. Therefore, compared to the cutting groove of the same width formed by etching through a single etching lines, instead of multiple etching lines, the stability and functionality of the formed cutting groove 350 can be further improved.

As described above, according to each of the embodiments of the invention, the metal mask structure can be formed with a cutting groove, which has an expected opening width larger than the width of the groove pattern, and the plate is left with a sufficient thickness, thereby reducing or avoiding unexpected erosion or truncation of the corresponding portion of the cutting groove of the metal mask structure. Therefore, the etching process of the cutting groove can be simplified, the stability and reliability of the metal mask structure can be improved, and the convenience of expected truncation of the metal mask structure can be improved.

The above descriptions are only some preferred embodiments of the present invention. It should be noted that various changes and modifications can be made to the present invention without departing from the spirit and principles of the present invention. A person of ordinary skill in the art should clearly understand that the present invention is defined by the appended claims, and all possible changes such as substitutions, combinations, modifications, and diversions are within the scope of the present invention defined by the appended claims in line with the purpose of this invention.

What is claimed is:

1. A metal mask structure comprising a plate, the plate at least comprising:
a pattern area formed with at least one slot;
a non-pattern area disposed on one side of the pattern area; and
a cutting groove extending along an extending direction between the pattern area and the non-pattern area,
wherein the cutting groove comprises an opening formed on a first surface of the plate and an inner groove surface concave with respect to the first surface,
wherein the plate further comprises at least one rib structure,
wherein the at least one rib structure is formed on the inner groove surface, extends along the extending direction, and does not protrude from the opening.

2. The metal mask structure according to claim 1, wherein portions of the inner groove surface divided by the at least one rib structure are each formed into a concave surface.

3. The metal mask structure according to claim 1, wherein the plate comprises a second surface opposite to the first surface, and a plate thickness between the inner groove surface and the second surface is larger than or equal to 6 μm.

4. The metal mask structure according to claim 3, wherein the plate thickness between the inner groove surface and the second surface is between 8 μm and 9 μm.

5. The metal mask structure according to claim 1, wherein the plate comprises a second surface opposite to the first surface, and a plate thickness between the first surface and the second surface of the plate is between 10 μm and 150 μm.

6. The metal mask structure according to claim 1, wherein the opening has an opening width perpendicular to the extending direction, on the first surface the at least one slot has a predetermined width parallel to a minor axis of the at least one slot, and the opening width is larger than the predetermined width.

7. The metal mask structure according to claim 6, wherein the plate comprises a second surface opposite to the first surface, and on the second surface the at least one slot has an enlarged predetermined width parallel to the minor axis; and
wherein the enlarged predetermined width is larger than the predetermined width.

8. The metal mask structure according to claim 6, wherein the opening width is between 80 μm and 120 μm, and the predetermined width is between 20 μm and 50 μm.

9. The metal mask structure according to claim 1, wherein the cutting groove is divided into at least two sections based on the at least one rib structure, and the at least two sections at least comprise adjacent first section and second section; and
wherein maximum section widths of the cutting groove respectively corresponding to the first section and the section perpendicular to the extending direction and parallel to the first surface are the same, and maximum section depths of the cutting groove respectively corresponding to the first section and the section perpendicular to the first surface are the same.

10. The metal mask structure according to claim 1, wherein the cutting groove is divided into at least two sections based on the at least one rib structure, and the at least two sections at least comprise adjacent first section and second section;
wherein in a direction perpendicular to the extending direction and parallel to the first surface, the cutting groove has a first section width and a second section width corresponding to the first section and the section, respectively;
wherein in a direction perpendicular to the first surface, the cutting groove has a maximum first depth and a maximum second depth corresponding to the first section and the section, respectively; and
wherein the first section is closer to a center of the cutting groove than the second section, the first section width is larger than the second section width, and the maximum first depth is deeper than the maximum second depth.

11. A photomask for exposing and developing a material layer to prepare a shielding layer, wherein the shielding layer is configured to shield a first surface of a plate during the etching process for preparing the metal mask structure of claim 1, wherein the photomask is configured corresponding to the metal mask structure, and the photomask at lease comprises:
at least one light shielding portion corresponding to the at least one slot to be formed; and
at least two light shielding sub-portions extending along a longitudinal direction and adjacently arranged side by side in a transverse direction perpendicular to the longitudinal direction,
wherein the at least two light shielding sub-portions jointly correspond to the cutting groove to be formed, and
wherein one or more spacing sections between the at least two light shielding sub-portions corresponds to the at least one rib structure to be formed.

12. The photomask according to claim 11, wherein each of the at least two light shielding sub-portions has a light shielding sub-portion width parallel to the transverse direction, and the light shielding sub-portion width is smaller than an opening width of the opening of the cutting groove to be formed in a direction perpendicular to the extending direction.

13. The photomask according to claim 12, wherein the light shielding sub-portion width is between 10 μm to 50 μm.

14. The photomask according to claim 13, wherein the opening width is between 80 μm to 120 μm.

15. The photomask according to claim 12, wherein the at least one light shielding portion has a light shielding portion width parallel to a minor axis direction of the at least one slot, and the light shielding sub-portion width is smaller than or equal to the light shielding portion width.

16. The photomask according to claim 11, wherein the shielding layer is used to shield the first surface of the plate in a predetermined etching process, so at least a portion of the at least one slot is opened on the first surface, and the cutting groove is formed as a single communicated groove in a region corresponding to the at least two light shielding sub-portions.

17. The photomask according to claim 16, wherein the predetermined etching process is a chemical wet etching process.

18. The photomask according to claim 11, wherein the at least two light shielding sub-portions at least comprise adjacent first light shielding sub-portion and second light shielding sub-portion; and
wherein in a direction parallel to the transverse direction, a width of the first light shielding sub-portion is equal to a width of the second light shielding sub-portion.

19. The photomask according to claim 11, wherein the at least two light shielding sub-portions at least comprise adjacent first light shielding sub-portion and second light shielding sub-portion;
wherein the first light shielding sub-portion has a first light shielding sub-portion width parallel to the transverse direction, and the second light shielding sub-portion has a second light shielding sub-portion width parallel to the transverse direction; and
wherein the first light shielding sub-portion is closer to a center of the cutting groove to be formed than the second light shielding sub-portion, and the first light shielding sub-portion width is larger than the second light shielding sub-portion width.

20. A method for preparing a metal mask structure, comprising:
preparing a plate;
disposing a material layer on a first surface of the plate;
exposing and developing the material layer based on the photomask of claim 11; and
by using a shielding layer resulted from the step of exposing and developing the material layer as a mask, performing a chemical etching process to etch a portion of the plate that is not covered by the shielding layer to form the metal mask structure or a semi-finished product of the metal mask structure.
